(19) United States
(12) Patent Application Publication
(10) Pub. No.: US 2026/0066668 A1
(43) Pub. Date: Mar. 5, 2026

(54) CONTROL METHOD OF TANDEM SOLAR CELL

(71) Applicant: TOYOTA JIDOSHA KABUSHIKI KAISHA, Toyota-shi (JP)

(72) Inventors: Yuya OKUDA, Nisshin-shi (JP); Ryuzo TAGAMI, Toyota-shi (JP); Shoichi IWAMOTO, Fuji-shi (JP); Ryota MORIKAWA, Osaka (JP); Shinya IWASAKI, Mizuho-shi (JP); Shintaro HINATA, Toyota-shi (JP); Hiroki USHIO, Toyota-shi (JP)

(73) Assignee: TOYOTA JIDOSHA KABUSHIKI KAISHA, Toyota-shi (JP)

(21) Appl. No.: 19/173,925

(22) Filed: Apr. 9, 2025

(30) Foreign Application Priority Data
Aug. 30, 2024 (JP) 2024-148085

(51) Int. Cl. H02J 3/46; H02J 3/00; H10K 39/15

(52) U.S. Cl. CPC H02J 3/46; H02J 3/004; H10K 39/15; H02J 2101/25

(57) ABSTRACT

A control method of a tandem solar cell includes: determining a P-V curve of a silicon solar cell by performing scanning for generated electric power while changing a generated voltage of the silicon solar cell at regular intervals; performing power generation control of the silicon solar cell at a maximal power point of a P-V curve; predicting an optimum power generation voltage appropriate for a perovskite solar cell using information regarding a P-V curve of the silicon solar cell; and performing power generation control of the perovskite solar cell using an optimum power generation voltage.

### CROSS-REFERENCE TO RELATED APPLICATION

This application claims priority to Japanese Patent Application No. 2024-148085 filed on Aug. 30, 2024. The disclosure of the above-identified application, including the specification, drawings, and claims, is incorporated by reference herein in its entirety.

### BACKGROUND

### 1. Technical Field

The present disclosure relates to a control method of a tandem solar cell.

### 2. Description of Related Art

Japanese Unexamined Patent Application Publication No. 2013-152687 (JP 2013-152687 A) discloses a solar cell power generation system. Generally, in power generation control of a silicon solar cell, a hill climbing method in maximum power point tracking (MPPT) control is executed. The hill climbing method is control in which power generation is executed while a maximal power point of a solar cell is constantly searched by current control. However, when there is a partial shadow (acceptance surface is partially in shade) on the solar cell, a plurality of peak points is generated in a power-voltage (P-V) curve, and accordingly there is a possibility that the maximal power point cannot be reached from among the peak points by the hill climbing method. Accordingly, it is common in power generation control of silicon solar cells to perform scanning of generated electric power at regular intervals in order to check whether a multiple peak points are being generated.

### SUMMARY

In recent years, tandem solar cells including silicon solar cells and perovskite solar cells have also come into use. However, perovskite solar cells have a response speed that is slower than that of silicon solar cells, and accordingly obtaining optimum generated voltage by scanning the generated electric power is difficult. Thus, technology that is capable of efficiently controlling power generation of tandem solar cells is desired.

The present disclosure can be realized as the following embodiments.

According to an aspect of the present disclosure, a control method of a tandem solar cell that includes a silicon solar cell and a perovskite solar cell is provided.

The control method includes
finding a P-V curve of the silicon solar cell by executing scanning to find generated electric power while changing generated voltage of the silicon solar cell at regular intervals, and also executing power generation control of the silicon solar cell at a maximal power point of the P-V curve,
predicting an optimum power generation voltage that is appropriate for the perovskite solar cell, using information relating to the P-V curve, and
executing power generation control of the perovskite solar cell, using the optimum power generation voltage.

According to this control method, an optimum power generation voltage that is appropriate for a perovskite solar cell is predicted using information relating to the P-V curve of the silicon solar cell. Accordingly, efficient power generation control can be executed in a short time, as compared to when performing scanning of the generated electric power with respect to the perovskite solar cell.

In the above control method, the information relating to the P-V curve may include a voltage value of the maximal power point.

According to this control method, the optimum power generation voltage of the perovskite solar cell can be easily predicted using the voltage value of the maximal power point of the silicon solar cell.

In the above control method, the information relating to the P-V curve may include a voltage value and a power value for one or more peak power points in the P-V curve.

According to this control method, the optimum power generation voltage of the perovskite solar cell can be accurately predicted by using the voltage value and the power value of one or more peak power points in the P-V curve of the silicon solar cell.

In the above control method, the information relating to the P-V curve may include profile data representing a profile of the P-V curve.

According to this control method, the optimum power generation voltage of the perovskite solar cell can be accurately predicted using the profile data of the P-V curve of the silicon solar cell.

The above control method may further include
predicting the optimum power generation voltage that is appropriate for the perovskite solar cell using the information relating to the P-V curve, and executing the power generation control of the perovskite solar cell using the optimum power generation voltage, when the P-V curve includes two or more peak power points, and
executing maximum power point tracking (MPPT) control of the perovskite solar cell, when the P-V curve includes only one peak power point.

According to this control method, efficient power generation control can be executed for perovskite solar cells.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a conceptual diagram of a tandem solar cell according to a first embodiment;

FIG. 2 is a block diagram of the solar cell power generation system according to the first embodiment;

FIG. 3 is a graph showing a P-V curve of a silicon solar cell and a predicted P-V curve of a perovskite solar cell in the absence of partial shading;

FIG. 4 is a graph showing a P-V curve of a silicon solar cell and a predicted P-V curve of a perovskite solar cell with partial shading;

FIG. 5 is a flow chart of power generation control of the tandem solar cell according to the first embodiment; and

FIG. 6 is a flowchart of power generation control of the tandem solar cell according to the second embodiment.

### DETAILED DESCRIPTION OF EMBODIMENTS

### A. First Embodiment

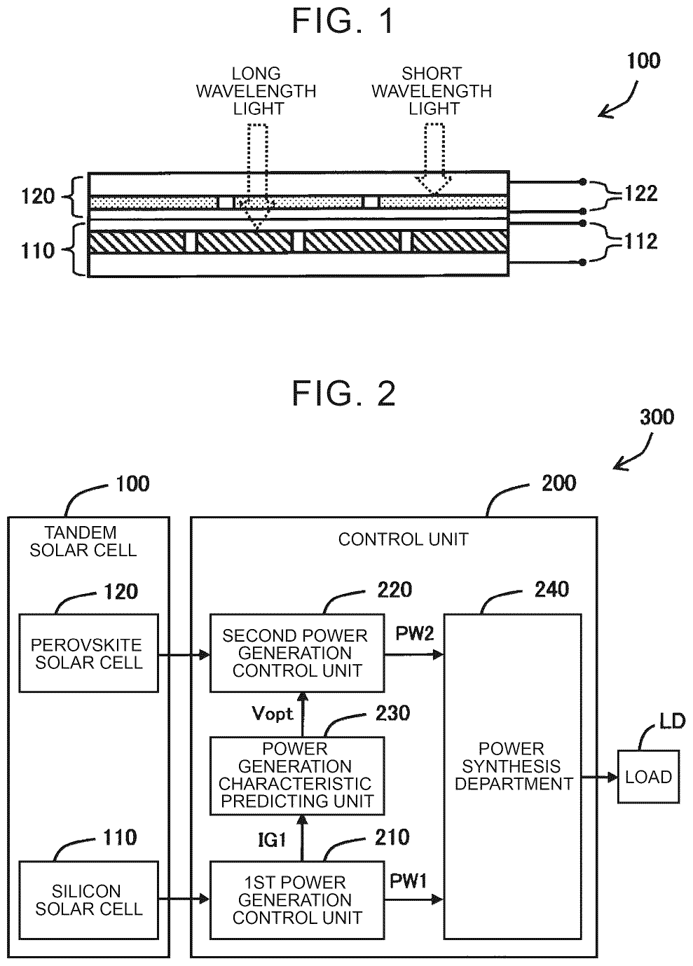

FIG. 1 is a conceptual diagram of a tandem solar cell 100 according to a first embodiment. The tandem solar cell 100 has a structure in which a silicon solar cell 110 and a perovskite solar cell 120 are stacked. The silicon solar cell 110 and the perovskite solar cell 120 each have a plurality of photoelectric conversion layers. The tandem solar cell 100 is a four-terminal cell in which the silicon solar cell 110 and the perovskite solar cell 120 are not electrically connected. That is, the silicon solar cell 110 has two terminals 112, and the perovskite solar cell 120 also has two terminals 122. The perovskite solar cell 120 absorbs light having a short wavelength, which is mainly visible light, and the silicon solar cell absorbs light having a long wavelength from visible light to infrared light.

FIG. 2 is a block diagram of the solar cell power generation system 300 according to the first embodiment. The solar cell power generation system 300 includes a tandem solar cell 100 and a control unit 200. The control unit 200 includes a first power generation control unit 210, a second power generation control unit 220, a power generation characteristic predicting unit 230, and a power combining unit 240.

The first power generation control unit 210 executes power generation control of the silicon solar cell 110. Specifically, the first power generation control unit 210 is configured to be capable of executing a first process of executing a hill climbing method of MPPT control on the silicon solar cell 110, and a second process of executing scanning for obtaining generated electric power while changing the generated voltage at regular intervals to obtain a P-V curve (power-voltage curve) of the silicon solar cell 110.

The power generation characteristic predicting unit 230 predicts P-V curve of the perovskite solar cell 120 using the information IG1 regarding P-V curve of the silicon solar cell 110, and predicts the optimum power generation voltage Vopt appropriate for the perovskite solar cell 120. This content will be described later.

The second power generation control unit 220 performs power generation control of the perovskite solar cell 120. Specifically, the second power generation control unit 220 is configured to be capable of executing the first process of executing the hill climbing method of MPPT control on the perovskite solar cell 120 and the second process of executing the power generation control of the perovskite solar cell 120 using the optimum power generation voltage Vopt predicted by the power generation characteristic predicting unit 230.

The power combining unit 240 combines the generated electric power PW1 of the silicon solar cell 110 obtained under the control of the first power generation control unit 210 and the generated electric power PW2 of the perovskite solar cell 120 obtained under the control of the second power generation control unit 220, and supplies the combined power to an external load LD.

The functions of the first power generation control unit 210, the second power generation control unit 220, and the power generation characteristic predicting unit 230 can be realized by a processor executing a computer program stored in a memory. Part or all of the functions of the first power generation control unit 210, the second power generation control unit 220, and the power generation characteristic predicting unit 230 may be realized by a hardware circuit.

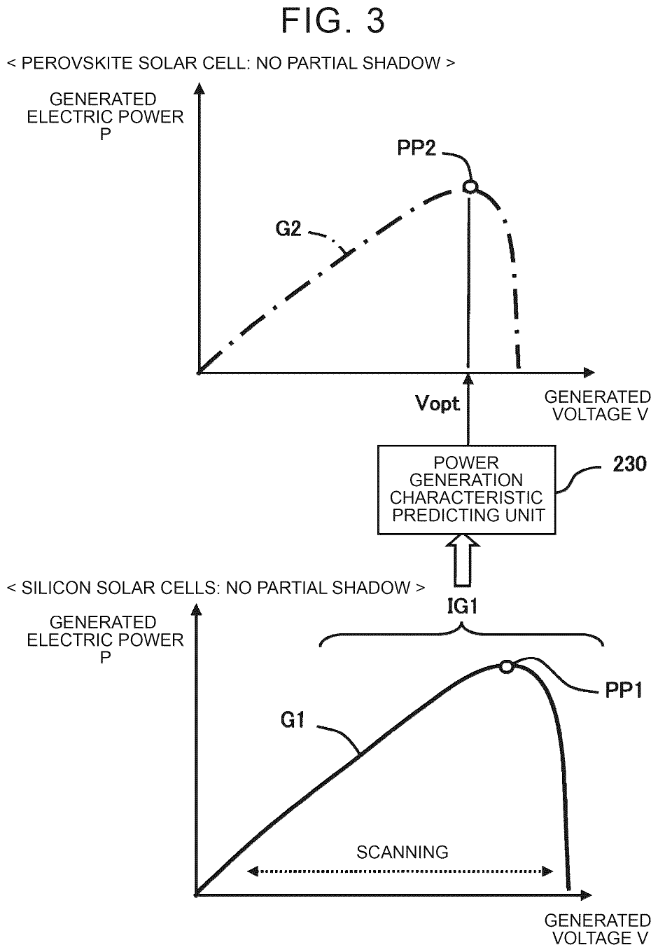

FIG. 3 is a graph showing P-V curve G1 of the silicon solar cell 110 and the predicted P-V curve G2 of the perovskite solar cell 120 in the absence of partial shading. “Partial shadow” means a state in which a shadow is formed on a part of the surface of the tandem solar cell 100 by clouds, external objects such as buildings, trees, and the like. When there is no partial shadow and the entire surface of the tandem solar cell 100 is exposed to light, P-V curve G1 of the silicon solar cell 110 has a chevron profile including only one peak power point PP1. The predicted P-V curve G2 of the perovskite solar cell 120 also has a chevron profile that includes only one peak power point PP2.

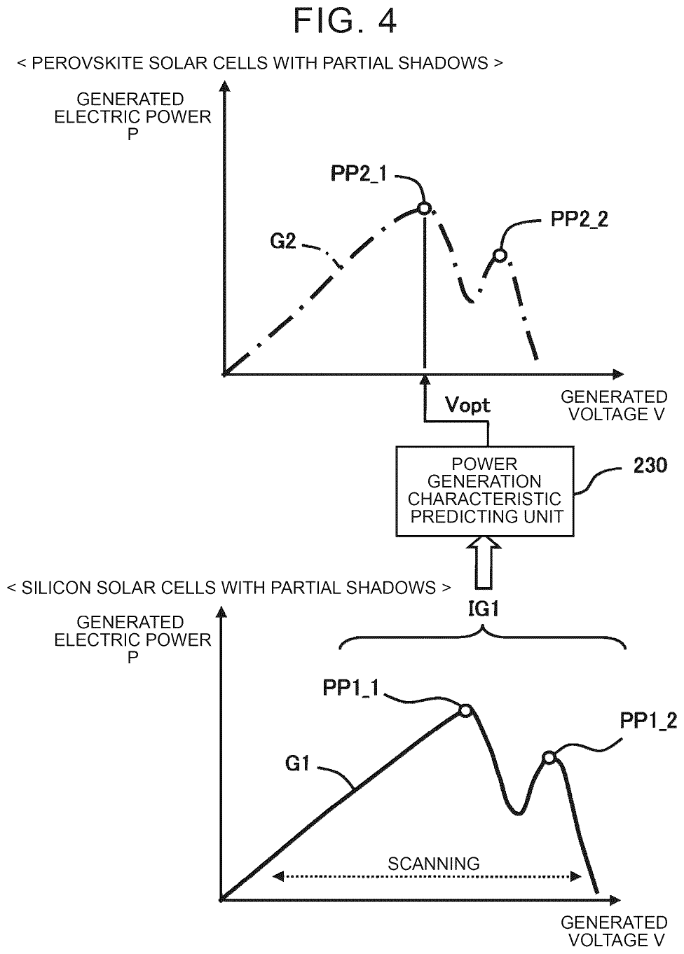

FIG. 4 is a graphical representation of P-V curve G1 of the silicon solar cell 110 and the predicted P-V curve G2 of the perovskite solar cell 120 in the presence of partial shading. When there is a partial shadow, P-V curve G1 of the silicon solar cell 110 is mountain-profiled including a plurality of peak power points PP1_1, PP1_2. The predicted P-V curve G2 of the perovskite solar cell 120 is similarly profiled in the mountain range including a plurality of peak power points PP2_1, PP2_2. Note that P-V curve G1, G2 shown in FIGS. 3 and 4 are merely examples because the profiles and sizes of P-V curve G1, G2 vary depending on the number of photoelectric conversion layers and the connecting methods.

The profiles of P-V curved G1 of the silicon solar cells 110 illustrated in FIGS. 3 and 4 can be confirmed by performing scanning for the generated electric power while changing the generated voltage of the silicon solar cells 110. On the other hand, since the perovskite solar cell 120 has a slower response rate when irradiated with light than the silicon solar cell 110, it is difficult to obtain the profile of P-V curved G2 at a practical scanning time. Therefore, the power generation characteristic predicting unit 230 predicts the optimum power generation voltage Vopt appropriate for the perovskite solar cell 120 using the information IG1 regarding P-V curve G1 of the silicon solar cell 110, and the second power generation control unit 220 executes the power generation control of the perovskite solar cell 120 using the optimum power generation voltage Vopt.

In the first embodiment, as shown in FIG. 3, even when P-V curve G1 of the silicon solar cell 110 includes only one peak power point PP1, an optimum power generation voltage Vopt appropriate for the perovskite solar cell 120 is predicted using the information IG1 regarding P-V curve G1. However, when P-V curve G1 includes only one peak power point PP1, MPPT control may be performed on the perovskite solar cell 120. This content will be described in the second embodiment.

As the information IG1 related to P-V curve G1 of the silicon solar cell 110, for example, one of the information IG1_a to the information IG1_c can be used. The information IG1_a is the voltage value at P-V curve G1 maximal power point. The information IG1_b is a voltage value and a power value of one or more peak power points PP1 in P-V curve G1. The information IG1_c is the data representing the profile of P-V curve G1. The profile data representing the profile of P-V curve G1 is, for example, one-dimensional data indicating the generated electric power value for each of the plurality of voltage values set at regular intervals.

The optimum power generation voltage Vopt of the perovskite solar cell 120 is a voltage corresponding to the maximal power point in the predicted P-V curve G2 of the perovskite solar cell 120. The second power generation control unit 220 performs power generation control of the perovskite solar cell 120 using the predicted optimum power generation voltage Vopt. In this way, it is possible to perform efficient power generation control in a short time as compared with a case where scanning related to generated electric power is performed on the perovskite solar cell 120.

The predicting function of the power generation characteristic predicting unit 230 may be realized by, for example, a map indicating a relation between the information IG1 related to P-V curve G1 and the optimum power generation voltage Vopt, or may be realized by a look-up table in which the information IG1 related to P-V curve G1 is inputted and the optimum power generation voltage Vopt is outputted. Further, the function of the power generation property predicting unit 230 may be realized by using a machine learning model in which the information IG1 related to P-V curve G1 is input and the optimum power generation voltage Vopt is output.

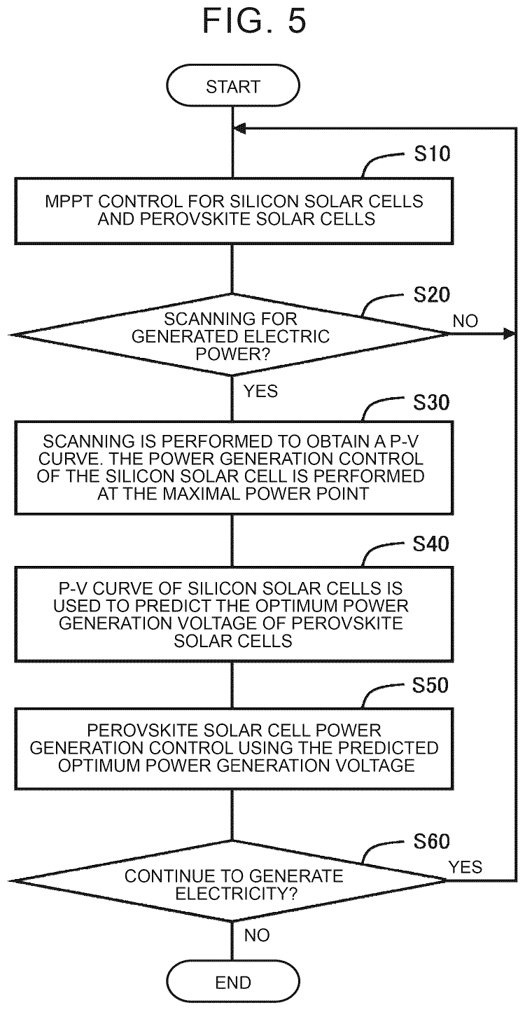

FIG. 5 is a flowchart of power generation control of the tandem solar cell 100 according to the first embodiment. In S10, the first power generation control unit 210 and the second power generation control unit 220 respectively perform MPPT control on the silicon solar cell 110 and the perovskite solar cell 120.

In S20, the first power generation control unit 210 determines whether or not it is the timing at which the scanning related to the generated electric power of the silicon solar cell 110 is executed. Scanning of the generated electric power of the silicon solar cell 110 is performed at a constant cycle. The scanning period is set in advance to, for example, about 1 minute to several minutes. The time required for one scanning is several seconds to several tens of seconds. When the scanning is not executed, the process returns to S10, and MPPT control for the silicon solar cell 110 and the perovskite solar cell 120 is continued. On the other hand, when the scanning execution timing is reached, S20 proceeds to S30.

In S30, the first power generation control unit 210 performs scanning on the generated electric power of the silicon solar cell 110 to obtain P-V curve G1, and performs power generation control of the silicon solar cell 110 at the maximal power point. In the embodiment of FIG. 3, the maximal power point of the silicon solar cell 110 is the only peak power point PP1. In FIG. 4, the maximal power point of the silicon solar cell 110 is the peak power point PP1_1 having the maximum power value among the plurality of peak power points PP1_1, PP1_2.

In S40, the power generation characteristic predicting unit 230 predicts the optimum power generation voltage Vopt of the perovskite solar cell 120 using the information IG1 regarding P-V curve G1 of the silicon solar cell 110. In S50, the second power generation control unit 220 performs power generation control of the perovskite solar cell 120 using the predicted optimum power generation voltage Vopt.

In S60, the control unit 200 determines whether or not to continue power generation of the tandem solar cell 100. When the power generation is to be continued, the process returns from S60 to S10, and the processes after S10 are executed again. On the other hand, when the power generation is not continued, the process of FIG. 5 is ended.

As described above, in the first embodiment, the optimum power generation voltage Vopt appropriate for the perovskite solar cell 120 is predicted using the information IG1 relating to P-V curve G1 of the silicon solar cell 110. Therefore, it is possible to perform efficient power generation control in a shorter time than in the case where scanning of the generated electric power is performed with respect to the perovskite solar cell 120.

### B. Second Embodiment

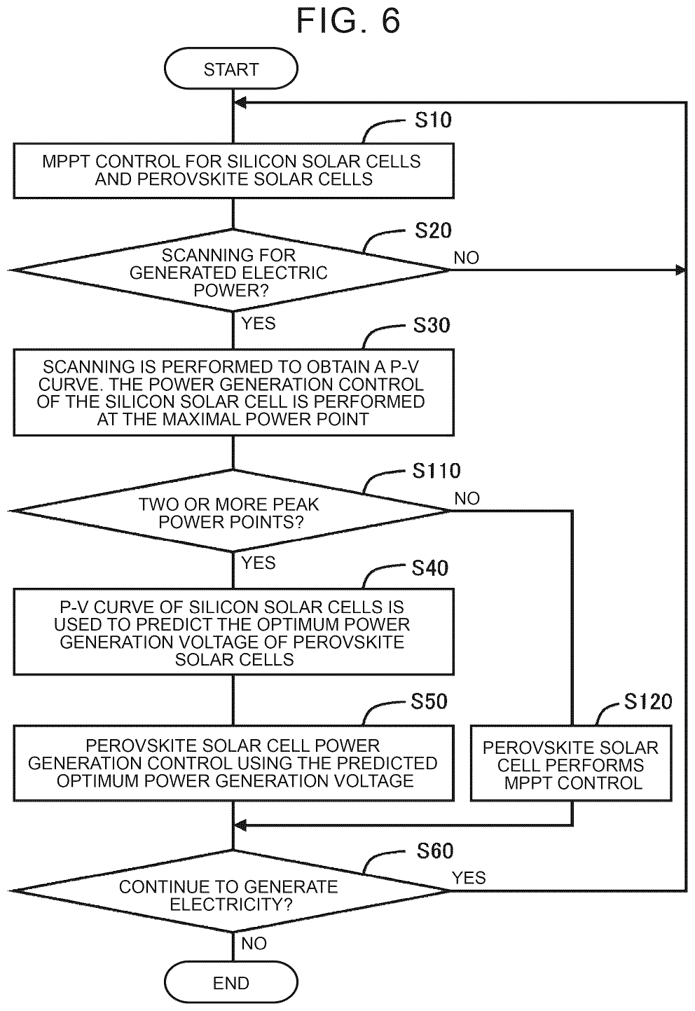

FIG. 6 is a flowchart of power generation control of the tandem solar cell 100 according to the second embodiment. The power generation control of the second embodiment is obtained by adding S110 and S120 to the power generation control of the first embodiment shown in FIG. 5, and the other steps are the same as those of the first embodiment. The apparatus configuration of the second embodiment is the same as the apparatus configuration of the first embodiment.

When P-V curve G1 of the silicon solar cell 110 is obtained in S30, the power generation characteristic predicting unit 230 determines whether or not two or more peak power points are included in P-V curve G1 of the silicon solar cell 110 in S110. When two or more peak power points are included in P-V curve G1, S40,S50 process is executed as in the first embodiment. On the other hand, when only one peak power point is included in P-V curve G1, the process proceeds to S120, and the second power generation control unit 220 performs MPPT control on the perovskite solar cell 120, and proceeds to S60.

As described above, in the second embodiment, when P-V curve G1 of the silicon solar cell 110 has two or more peak power points, the optimum power generation voltage Vopt of the perovskite solar cell 120 is predicted using the information IG1 related to P-V curve G1, and the power generation control of the perovskite solar cell 120 is performed using the optimum power generation voltage Vopt. On the other hand, when P-V curve G1 of the silicon solar cell 110 has only one peak power point, MPPT control is performed on the perovskite solar cell 120. Therefore, it is possible to perform efficient power generation control for the perovskite solar cell 120 depending on whether or not the tandem solar cell 100 has a partial shadow.

### Other Forms

The present disclosure is not limited to the above-described embodiments, and can be realized in various forms without departing from the spirit thereof. For example, the present disclosure can also be realized by the following aspect. The technical features in the above-described embodiments corresponding to the technical features in the respective embodiments described below can be appropriately replaced or combined in order to solve some or all of the problems of the present disclosure or to achieve some or all of the effects of the present disclosure. In addition, if the technical features are not described as essential in the present specification, they can be deleted as appropriate.

The present disclosure can be implemented in various forms other than a control method of a tandem solar cell. For example, the present disclosure can be realized in the form of a control system for a tandem solar cell, a computer program for executing a control method for a tandem solar cell, a non-transitory recording medium (non-transitory storage medium) in which a computer program is recorded, and the like.

What is claimed is:

1. A control method of a tandem solar cell that includes a silicon solar cell and a perovskite solar cell, the control method comprising:
finding a P-V curve of the silicon solar cell by executing scanning to find generated electric power while changing generated voltage of the silicon solar cell at regular intervals, and also executing power generation control of the silicon solar cell at a maximal power point of the P-V curve;
predicting an optimum power generation voltage that is appropriate for the perovskite solar cell, using information relating to the P-V curve; and
executing power generation control of the perovskite solar cell, using the optimum power generation voltage.

2. The control method according to claim 1, wherein the information relating to the P-V curve includes a voltage value of the maximal power point.

3. The control method according to claim 1, wherein the information relating to the P-V curve includes a voltage value and a power value for one or more peak power points in the P-V curve.

4. The control method according to claim 1, wherein the information relating to the P-V curve includes profile data representing a profile of the P-V curve.

5. The control method according to claim 1, further comprising:
predicting the optimum power generation voltage that is appropriate for the perovskite solar cell using the information relating to the P-V curve, and executing the power generation control of the perovskite solar cell using the optimum power generation voltage, when the P-V curve includes two or more peak power points; and
executing maximum power point tracking (MPPT) control of the perovskite solar cell, when the P-V curve includes only one peak power point.
